(19) United States
(12) Patent Application Publication
(10) Pub. No.: US 2024/0196559 A1
(43) Pub. Date: Jun. 13, 2024

(54) COMPUTER FAN WITH A HOLLOW WIRE-PASSING SHAFT

(71) Applicant: Kuan-Hao PENG, Dongguan (CN)

(72) Inventor: Kuan-Hao PENG, Dongguan (CN)

(21) Appl. No.: 18/128,242

(22) Filed: Mar. 30, 2023

(30) Foreign Application Priority Data
Dec. 8, 2022 (CN) 202211582858.4

(51) Int. Cl. H05K 7/20; F04D 19/00; F04D 29/32; G06F 1/20

(52) U.S. Cl. CPC H05K 7/20172; F04D 19/002; F04D 29/325; G06F 1/20

(57) ABSTRACT

The present invention discloses a computer fan with a hollow wire-passing shaft, which comprises a frame body and a wire-passing pipe, the upper end of the wire-passing pipe extends out of the upper wall of the impeller shaft, and is provided with a fixed seat which is provided with an LCD screen which can display predetermined patterns. The LCD screen is connected with the corresponding wire body via the wire-passing channel to simplify the wiring of the wire body wherein the LCD screen can display the corresponding LOGO or the fonts or patterns, providing diversified options.

### BACKGROUND OF THE INVENTION

The present invention relates to the field of computing fans, in particular relates to a computer fan with a hollow wire-passing shaft.

The computer fans are mainly used to dissipate the heat from the heating elements of the computers to prevent the normal use of the heating elements (such as power supply, graphics card or CPU) from being affected due to high temperature. With the development of computer design, the requirements for the appearance of the computer fans have become higher; therefore, the corresponding lighting equipment is arranged for the computer fans; however, the wiring of the existing lighting equipment is disordered and the assembly is also troublesome. Moreover, the DIY enthusiasts like disassembling the computer fans for refitting; if they find that the internal design of products is poor, they may not accept the products.

### BRIEF SUMMARY OF THE INVENTION

The main purpose of the present invention is to provide a computer fan with a hollow wire-passing shaft in order to improve the structures of the existing computer fans, improve the wiring design of the fans, facilitate the assembly of the computer fans, and provide better visual lighting effect.

In order to realize the above purpose, the present invention provides a computer fan with a hollow wire-passing shaft, comprising:
a frame body, wherein the middle part of the said frame body is provided with a through channel, the middle part of the said through channel is provided with a base, the middle part of the said base is provided with a through locating orifice;
and a wire-passing pipe, wherein the said wire-passing pipe is a pipe body with a wire-passing channel, the bottom of the said wire-passing pipe is installed in the locating orifice, the outer wall of the said wire-passing pipe is provided with a pivoting pipe, and the upper part of the said pivoting pipe is provided with an impeller shaft, and the said impeller shaft is extended with a bent casing body, and the said casing body and the base form a holding cavity, the said base is provided with a PCB which is provided a stator, and the said stator is arranged in the holding cavity, and the inner wall of the said casing body is provided with a rotor which matches the said stator;
the upper end of the wire-passing pipe extends out of the upper wall of the impeller shaft, and is provided with a fixed seat which is provided with an LCD screen which can display predetermined patterns.

Concretely, the said pivoting pipe is a copper pipe, a first ball bearing and a second ball bearing are spaced between the said pivoting pipe and the said wire-passing pipe, the inner wall of the said pivoting pipe is internally convex with a first locating part and a second locating part, the said first locating part is fitted with the upper wall of the said first ball bearing and the said second locating part is fitted with the outer wall of the said second ball bearing.

Concretely, the said impeller shaft is provided with a hooking part, the said copper pipe is provided with a clamping part matching the hooking part, and the said hooking part is clamped and fixed with the clamping part.

Concretely, an ejecting spring is arranged between the said first locating part and the said second ball bearing.

Concretely, a gasket is arranged between the said PCB and the said base.

Concretely, the outer wall of the lower end of the said wire-passing pipe is provided with a limiting part, the diameter of the said limiting part is greater than the diameter of the said locating orifice, and the said locating orifice is provided with a limiting groove which matches the limiting part.

Concretely, the said limiting part is provided with a groove, and the said groove is provided with a resilient washer.

Concretely, the said base extends upward with an encircling part, which is arranged oppositely to with the hooking part.

Concretely, the inner wall of the said stator fixes the outer wall of the said encircling part.

Concretely, the peripheral wall of the said fixed seat is provided with a terracing part, and the said LCD screen is arranged on the said terracing part.

In the specific installation process of the technical solutions of the present invention, the installation workers use plastic to integrally mold the frame body and the base, and then install the wire-passing pipe in the locating orifice, and then install the impeller shaft onto the pivoting pipe and fixedly install the rotor on the inner wall of the casing body, and then integrally install the stator and the PCB on the base, and then install the pivoting pipe onto the outer wall of the wire-passing pipe, and then install the fixed seat onto the upper wall of the wire-passing pipe, and then connect the corresponding wire body with the LCD screen via the wire-passing channel and thus further simplify the wiring of the wire body; certainly, in the specific embodiments, the LCD screen also can act as an LED assembly to realize the same aesthetic effect; however, the LCD screen can display the corresponding LOGO or fonts or patterns, providing diversified options; such LCD screen plays a role in advertising the related brands or producers; certainly, the LCD screen can also directly control the display effect as per the computer by means of the corresponding chips set in the fixed seat. The present invention firmly fixes the LCD screen by means of the shaft-to-shaft structure and forms a certain downward pressure on the upper wall of the impeller; the arrangement of the fixed seat ensures stable high-speed rotation of the impeller.

### BRIEF DESCRIPTION OF THE DRAWINGS

FIG. 1 is a three-dimensional sectional view of the present invention;

FIG. 2 is a sectional view of the present invention;

FIG. 3 is an exploded view of the present invention;

FIG. 4 is a schematic diagram of the wire-passing pipe.

In the figures, 1—frame body; 11—through channel; 12—base; 13—locating orifice; 2—wire-passing pipe; 21—wire-passing channel; 22—wire body; 3—pivoting pipe; 31—impeller shaft; 32—casing body; 33—holding cavity; 4—PCB; 40—gasket; 41—stator; 5—rotor; 51—fixed seat; 52—LCD screen; 61—first ball bearing; 62—second ball bearing; 63—first locating part; 64—second locating part; 65—hooking part; 66—clamping part; 64—second locating part; 65—hooking part; 66—clamping part; 67—ejecting spring; 71—limiting part; 72—limiting groove; 81—groove; 82—resilient washer; 9—encircling part; 91—terracing part.

### DETAILED DESCRIPTION OF THE INVENTION

The technical solutions of the present invention will be described more clearly and fully in conjunction with the accompanying drawings, and obviously, the described embodiments are merely a part of the embodiments of the present invention, not all the embodiments. Based on the embodiments of the present invention, all the other embodiments obtained by the ordinary skilled in the art without creative labors belong to the scope claimed by the present invention.

It should be noted that if an embodiment of the present invention relates to directive instructions (such as upper, lower, left, right, front, rear, top, bottom, inside, outside, vertical, transverse, longitudinal, counter-clockwise, clockwise, circumferential, radial and axial), these directive instructions are merely used to explain the relative position relationship, the movement and so on among the components at certain specific posture (as shown in the accompanying drawings); if the specific posture changes, the directive instructions should be changed accordingly.

In addition, if an embodiment of the present invention relates to the descriptions such as “first” and “second”, these descriptions are merely used for description and should not be understood to indicate or imply their relative importance or implicitly indicate the number of the corresponding technical features. This shows that the features limited with “first” and “second” can explicitly or implicitly include one such feature at least. Moreover, the technical solutions among the embodiments can be in combination with each other; however, such combination must be on the premise that those skilled in the art can realize the related technical solutions; when the technical solutions are inconsistent or cannot be realized, such combination of technical solutions should be deemed to be inexistent and not in the scope claimed by the present invention.

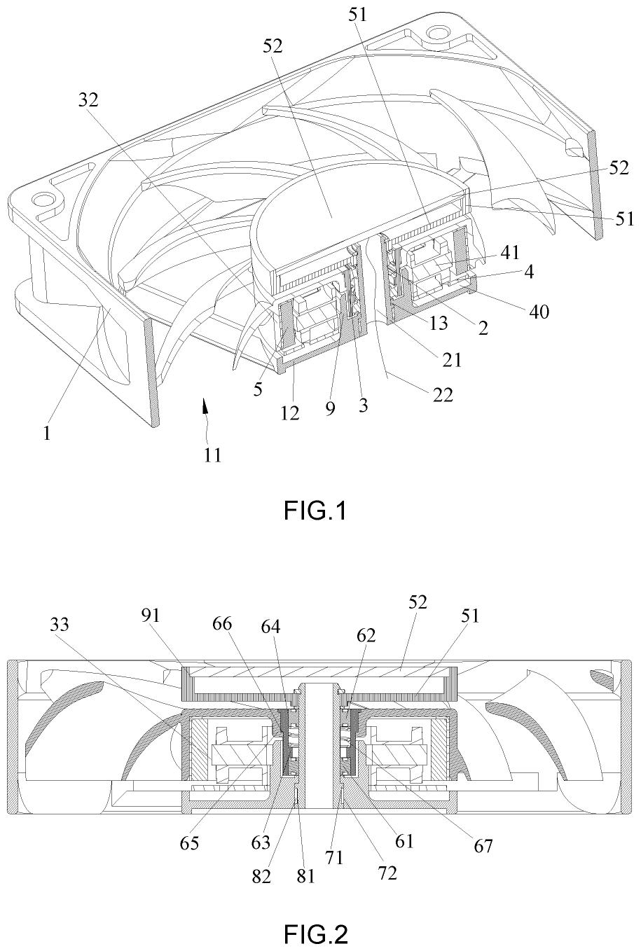

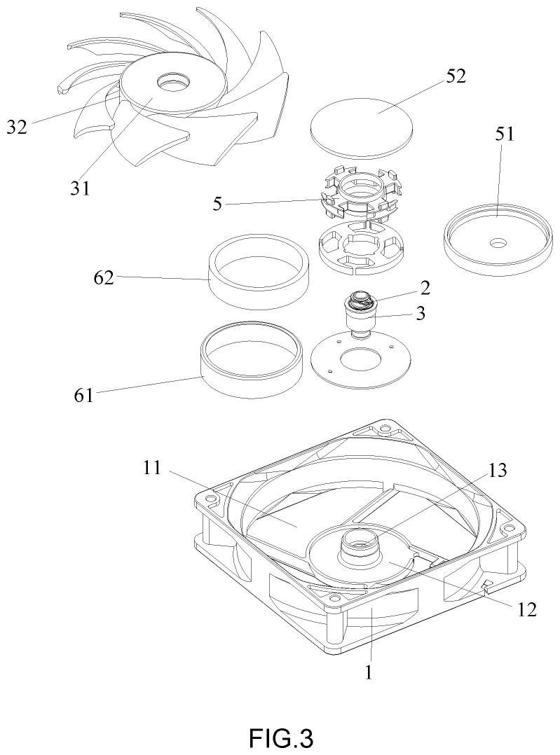

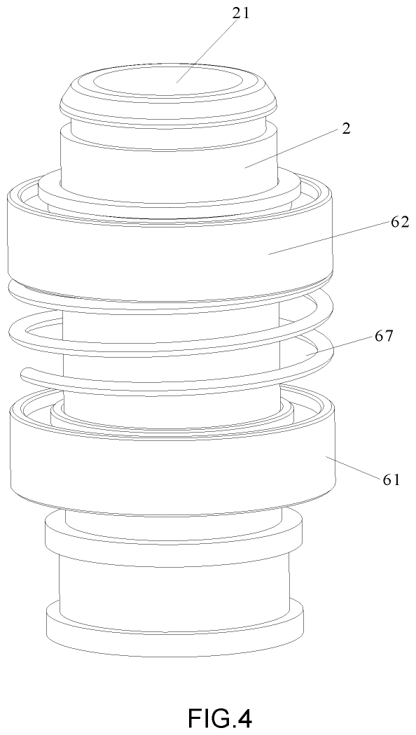

As shown from FIG. 1 to FIG. 4, a computer fan with a hollow wire-passing shaft comprises:
a frame body (1), wherein the middle part of the said frame body is provided with a through channel (11), the middle part of the said through channel (11) is provided with a base (12), the middle part of the said base (12) is provided with a through locating orifice (13);
and a wire-passing pipe (2), wherein the said wire-passing pipe (2) is a pipe body with a wire-passing channel (21), the bottom of the said wire-passing pipe (2) is installed in the locating orifice (13), the outer wall of the said wire-passing pipe (2) is provided with a pivoting pipe (3), and the upper part of the said pivoting pipe (3) is provided with an impeller shaft (31), and the said impeller shaft (31) is extended with a bent casing body (32) [wherein the impeller is arranged on the outer wall of the casing body (32)], and the said casing body (32) and the said base (12) form a holding cavity (33), the said base (12) is provided with a PCB (4) which is provided a stator (41), and the said stator (41) is arranged in the holding cavity (33), and the inner wall of the said casing body (32) is provided with a rotor (5) which matches the said stator (41);
the upper end of the wire-passing pipe (2) extends out of the upper wall of the impeller shaft (31), and is provided with a fixed seat (51) which is provided with an LCD screen (52) which can display predetermined patterns.

In the specific installation process, the installation workers use plastic to integrally mold the frame body (1) and the base (12), and then install the wire-passing pipe (2) in the locating orifice (13), and then install the impeller shaft (31) onto the pivoting pipe (3) and fixedly install the rotor (5) on the inner wall of the casing body (32), and then integrally install the stator (41) and the PCB (4) on the base (12), and then install the pivoting pipe (3) onto the outer wall of the wire-passing pipe (2), and then install the fixed seat (51) onto the upper wall of the wire-passing pipe (2), and then connect the corresponding wire body (22) with the LCD screen (52) via the wire-passing channel (21) and thus further simplify the wiring of the wire body (22); certainly, in the specific embodiments, the LCD screen (52) also can act as an LED assembly to realize the same aesthetic effect; however, the LCD screen (52) can display the corresponding LOGO or fonts or patterns, providing diversified options; such LCD screen plays a role in advertising the related brands or producers; certainly, the LCD screen (52) can also directly control the display effect as per the computer by means of the corresponding chips set in the fixed seat (51). The present invention fixes the LCD screen (52) by means of the shaft-to-shaft structure and forms a certain downward pressure on the upper wall of the impeller (blades); the arrangement of the fixed seat (51) ensures stable high-speed rotation of the impeller.

In the embodiments of the present invention, the said pivoting pipe (3) is a copper pipe, a first ball bearing (61) and a second ball bearing (62) are spaced between the said pivoting pipe (3) and the said wire-passing pipe (2), the inner wall of the said pivoting pipe (3) is internally convex with a first locating part (63) and a second locating part (64), the said first locating part (63) is fitted with the upper wall of the said first ball bearing (61) and the said second locating part (64) is fitted with the outer wall of the said second ball bearing (62). In this way, the present invention realizes both the stability and the high speed of the impeller rotation; the arrangement of the ball bearings can also ensure the minimum friction of the pivoting pipe (3); in addition, the arrangement of the copper pipe can also ensure the service life of the copper pipe; moreover, the copper pipe has a certain gravity, which also ensures the stability and coaxiality of the impeller rotation.

Concretely, the said impeller shaft (31) is provided with a hooking part (65), the said copper pipe is provided with a clamping part (66) matching the hooking part (65), and the said hooking part is clamped and fixed with the clamping part (66). The impeller shaft (31) can be integrally molded with the copper pipe or fixed with glue to ensure stable installation of the impeller shaft (31).

More concretely, an ejecting spring (67) is arranged between the said first locating part (63) and the said second ball bearing (62). The arrangement of the ejecting spring can ensure to buffer the rising force of the impeller when the impeller is started and thus reduce the friction damage; in addition, the arrangement of the ejecting spring can realize the floating rotation of the impeller at a high rotating speed and thus avoid eccentric rotation; the fixed seat (51) can limit the upper wall of the impeller shaft (31).

In the embodiments of the present invention, a gasket (40) is arranged between the PCB (4) and the base (12), and the arrangement of the gasket (40) can reduce the vibration arising from the rotation of the impeller.

Further, the outer wall of the lower end of the said wire-passing pipe (2) is provided with a limiting part (71), the diameter of the said limiting part (71) is greater than the diameter of the said locating orifice (13), and the said locating orifice (13) is provided with a limiting groove (72) which matches the limiting part and thus facilitates the installation of the wire-passing pipe (2).

Further, the limiting part (71) is provided with a groove (81), and the said groove (81) is provided with a resilient washer (82), and the arrangement of the resilient washer (82) can buffer the vibration while facilitating the fixing of the wire-passing pipe (2).

In the embodiments of the present invention, the base (12) is extended upward with an encircling part (9) and the said encircling part (9) is arranged oppositely to the hooking part (65); therefore, it is not necessary to arrange a casing for the motor in the actual assembly.

Further, the inner wall of the said stator (41) fixes the outer wall of the said encircling part (9).

In the embodiments of the present invention, the peripheral wall of the fixed seat (51) is provided with a terracing part (91), and the said LCD screen (52) is arranged onto the terracing part (91) and thus forms an electronic element with a fixed cavity for installing the LCD screen (52).

The embodiments described above are merely the preferred embodiments of the present invention, not to limit the patent scope of the present invention; with the inventive conception of the present invention, any equivalent structural transformation using the Specifications and the accompanying drawings of the present invention or direct/indirect applications to other related technical fields should be included in the scope claimed by the present invention.

What is claimed is:

1. A computer fan with a hollow wire-passing shaft, which is characterized in that it comprises:
a frame body, wherein the middle part of the said frame body is provided with a through channel, the middle part of the said through channel is provided with a base, the middle part of the said base is provided with a through locating orifice;
and a wire-passing pipe, wherein the said wire-passing pipe is a pipe body with a wire-passing channel, the bottom of the said wire-passing pipe is installed in the locating orifice, the outer wall of the said wire-passing pipe is provided with a pivoting pipe, and the upper part of the said pivoting pipe is provided with an impeller shaft, and the said impeller shaft is extended with a bent casing body, and the said casing body and the base form a holding cavity, the said base is provided with a PCB which is provided a stator, and the said stator is arranged in the holding cavity, and the inner wall of the said casing body is provided with a rotor which matches the said stator;
the upper end of the wire-passing pipe extends out of the upper wall of the impeller shaft, and is provided with a fixed seat which is provided with an LCD screen which can display predetermined patterns.

2. The computer fan with a hollow wire-passing shaft in accordance with claim 1, which is characterized in that the said pivoting pipe is a copper pipe, a first ball bearing and a second ball bearing are spaced between the said pivoting pipe and the said wire-passing pipe, the inner wall of the said pivoting pipe is internally convex with a first locating part and a second locating part, the said first locating part is fitted with the upper wall of the said first ball bearing and the said second locating part is fitted with the outer wall of the said second ball bearing.

3. The computer fan with a hollow wire-passing shaft in accordance with claim 2, which is characterized in that the said impeller shaft is provided with a hooking part, the said copper pipe is provided with a clamping part matching the hooking part, and the said hooking part is clamped and fixed with the clamping part.

4. The computer fan with a hollow wire-passing shaft in accordance with claim 2, which is characterized in that an ejecting spring is arranged between the said first locating part and the said second ball bearing.

5. The computer fan with a hollow wire-passing shaft in accordance with claim 1, which is characterized in that a gasket is arranged between the said PCB and the said base.

6. The computer fan with a hollow wire-passing shaft in accordance with claim 1, which is characterized in that the outer wall of the lower end of the said wire-passing pipe is provided with a limiting part, the diameter of the said limiting part is greater than the diameter of the said locating orifice, and the said locating orifice is provided with a limiting groove which matches the limiting part.

7. The computer fan with a hollow wire-passing shaft in accordance with claim 6, which is characterized in that the said limiting part is provided with a groove, and the said groove is provided with a resilient washer.

8. The computer fan with a hollow wire-passing shaft in accordance with claim 1, which is characterized in that the said base extends upward with an encircling part, which is arranged oppositely to with the hooking part.

9. The computer fan with a hollow wire-passing shaft in accordance with claim 1, which is characterized in that the inner wall of the said stator fixes the outer wall of the said encircling part.

10. The computer fan with a hollow wire-passing shaft in accordance with claim 1, which is characterized in that the peripheral wall of the said fixed seat is provided with a terracing part, and the said LCD screen is arranged on the said terracing part.
